(19) United States
(12) Patent Application Publication
(10) Pub. No.: US 2025/0284322 A1
(43) Pub. Date: Sep. 11, 2025

(54) HINGE DEVICE AND DISPLAY APPARATUS INCLUDING SAME

(71) Applicant: LG ELECTRONICS INC., Seoul (KR)

(72) Inventors: Dongwook KIM, Seoul (KR); Sungchul SHIN, Seoul (KR)

(73) Assignee: LG ELECTRONICS INC., Seoul (KR)

(21) Appl. No.: 18/692,550

(22) PCT Filed: Sep. 16, 2021
(86) PCT No.: PCT/KR2021/012677

§ 371 Date: Sep. 3, 2024

(51) Int. Cl. G06F 1/16; H05K 5/02

(52) U.S. Cl. CPC G06F 1/1681; G06F 1/1641; H05K 5/0226

(57) ABSTRACT

A hinge device and a display apparatus including the same are disclosed. The hinge device comprises: a first structure having a first guide groove; a second structure having a second guide groove; a first shaft disposed between the first structure and the second structure; a first link member connecting the first shaft to a second shaft; a second link member connecting the first shaft to a third shaft moved in the first guide groove; a third link member connecting the first shaft to a fourth shaft in the second structure; and a fourth link member connecting the first shaft to a fifth shaft moved in the second guide groove, wherein a length of the second link member is greater than a length of the first link member, and a length of the fourth link member is greater than a length of the third link member. Accordingly, it is possible to seamlessly contact the first structure and the second structure.

### BACKGROUND

### 1. Technical Field

The present disclosure relates to a hinge device and a display apparatus including the same, and more particularly, to a hinge device capable of seamlessly contacting a first structure and a second structure.

### 2. Description of the Related Art

A hinge device is a device disposed between a first body and a second body and configured to rotate at least one of the first body or the second body.

Korean Patent No. 10-2175166 (hereinafter referred to as related art 1) discloses a powered hinge mechanism.

In related art 1, the hinge mechanism is rotatably mounted between a first body and a second body.

However, the hinge mechanism in related art 1 projects above the first body and the second body, such that the first body and the second body may not be seamlessly connected.

### SUMMARY

It is an objective of the present disclosure to provide a hinge device and a display apparatus including the hinge device capable of seamlessly contacting a first structure and a second structure.

It is another objective of the present disclosure to provide a hinge device and a display apparatus including the hinge device capable of seamlessly contacting a first structure and a second structure while avoiding interference in a moving path during movement of the first structure and the second structure.

It is further another objective of the present disclosure to provide a hinge device and a display apparatus including the hinge device capable of being spaced apart from a first structure and a second structure in a first mode, and seamlessly contacting each other in a second mode.

It is further another objective of the present disclosure to provide a display apparatus capable of being folded or unfolded by using a hinge device and a plurality of display elements.

It is further another objective of the present disclosure to provide a cuboid-shaped display apparatus by using a hinge device and a plurality of display elements.

A hinge device according to an embodiment of the present disclosure comprises: a first structure having a first guide groove formed in a first diagonal direction; a second structure having a second guide groove formed in a second diagonal direction; a first shaft disposed between the first structure and the second structure and spaced apart from the first structure and the second structure; a first link member connecting the first shaft to a second shaft formed in the first structure; a second link member connecting the first shaft to a third shaft moved in the first guide groove of the first structure; a third link member connecting the first shaft to a fourth shaft formed in the second structure; and a fourth link member connecting the first shaft to a fifth shaft moved in the second guide groove of the second structure, wherein a length of the second link member is greater than a length of the first link member, and a length of the fourth link member is greater than a length of the third link member.

Meanwhile, the first structure and the second structure may be spaced apart from each other in a first mode, and, in a second mode, a first surface of the first structure may be contacted with a first surface of the second structure.

Meanwhile, the third shaft may be disposed at a first position in the first guide groove in the second mode, and the third shaft may be disposed at a second position in the first guide groove in the first mode, wherein the first position may correspond to a furthest position from the third shaft, and the second position may correspond to a closest position to the third shaft.

Meanwhile, in response to switching from the second mode to the first mode, the third shaft may move from the first position to the second position, and in response to switching from the first mode to the second mode, the third shaft may move from the second position to the first position.

Meanwhile, an angle between the first link member and the second link member in the second mode may be greater than an angle between the first link member and the second link member in the first mode.

Meanwhile, only the second link member may project out of the first structure in the second mode, and both the first link member and the second link member may project out of the first structure in the first mode.

Meanwhile, the first link member in the first mode may project out of the first structure.

Meanwhile, the first diagonal direction may correspond to an opening direction of the first guide groove in the second shaft, and the second diagonal direction may correspond to an opening direction of the second guide groove in the fourth shaft.

Meanwhile, the first surface of the first structure and the first surface of the second structure may be spaced apart from each other and located on a same line in the first mode.

Meanwhile, a distance between the first shaft and the second shaft in the second mode may be equal to a distance between the first shaft and the second shaft in the first mode, and a distance between the first shaft and the third shaft in the second mode may be equal to a distance between the first shaft and the third shaft in the first mode.

Meanwhile, the distance between the first shaft and the third shaft may be greater than the distance between the first shaft and the second shaft in the second mode, and the distance between the first shaft and the third shaft may be greater than the distance between the first shaft and the second shaft in the first mode.

Meanwhile, a distance between the second shaft and the third shaft in the first mode may be less than a distance between the second shaft and the third shaft in the second mode.

Meanwhile, the hinge device according to an embodiment of the present disclosure may further include: a fifth link member contacted between a first display element and a second surface intersecting the first surface of the first structure; and a sixth link member contacted between a second display element and a second surface intersecting the first surface of the second structure.

Meanwhile, a side surface of the first display element may be contacted with a side surface of the second display element in the second mode, and the first display element and the second display element may be spaced apart from each other in the first mode.

Meanwhile, the first display element and the second display element may include right-angled triangular display elements.

Meanwhile, a hinge device according to another embodiment of the present disclosure comprises: a first structure having a first guide groove formed in a first diagonal direction; a second structure having a second guide groove formed in a second diagonal direction; a first shaft disposed between the first structure and the second structure and spaced apart from the first structure and the second structure; a first link member connecting the first shaft to a second shaft formed in the first structure; a second link member connecting the first shaft to a third shaft moved in the first guide groove of the first structure; a third link member connecting the first shaft to a fourth shaft formed in the second structure; and a fourth link member connecting the first shaft to a fifth shaft moved in the second guide groove of the second structure, wherein, in a second mode, a first surface of the first structure is contacted with a first surface of the second structure, and, in a first mode, the first structure is spaced apart from the second structure.

Meanwhile, an image display apparatus according to an embodiment of the present disclosure comprises a hinge device.

Meanwhile, the image display apparatus according to an embodiment of the present disclosure may further include a plurality of display elements, wherein the plurality of display elements may be folded in a direction of the first shaft in the first mode, and at least a portion of the plurality of display elements may be unfolded to form a polyhedral display.

Meanwhile, the plurality of display elements may include right-angled triangular origami display elements.

### EFFECT OF THE DISCLOSURE

A hinge device according to an embodiment of the present disclosure comprises: a first structure having a first guide groove formed in a first diagonal direction; a second structure having a second guide groove formed in a second diagonal direction; a first shaft disposed between the first structure and the second structure and spaced apart from the first structure and the second structure; a first link member connecting the first shaft to a second shaft formed in the first structure; a second link member connecting the first shaft to a third shaft moved in the first guide groove of the first structure; third link member connecting the first shaft to a fourth shaft formed in the second structure; and a fourth link member connecting the first shaft to a fifth shaft moved in the second guide groove of the second structure, wherein a length of the second link member is greater than a length of the first link member, and a length of the fourth link member is greater than a length of the third link member. Accordingly, the first structure and the second structure may seamlessly contact each other. Particularly, the first structure and the second structure may seamlessly contact each other while avoiding interference in a moving path during movement of the first structure and the second structure.

Meanwhile, the first structure and the second structure may be spaced apart from each other in a first mode, and, in a second mode, a first surface of the first structure may be contacted with a first surface of the second structure. Accordingly, the first structure and the second structure may be spaced apart from each other in the first mode, and the first structure and the second structure may seamlessly contact each other in the second mode.

Meanwhile, the third shaft may be disposed at a first position in the first guide groove in the second mode, and the third shaft may be disposed at a second position in the first guide groove in the first mode, wherein the first position may correspond to a furthest position from the third shaft, and the second position may correspond to a closest position to the third shaft. Accordingly, the first structure and the second structure may be spaced apart from each other in the first mode, and the first structure and the second structure may seamlessly contact each other in the second mode.

Meanwhile, in response to switching from the second mode to the first mode, the third shaft may move from the first position to the second position, and in response to switching from the first mode to the second mode, the third shaft may move from the second position to the first position. Accordingly, the first structure and the second structure may be spaced apart from each other in the first mode, and the first structure and the second structure may seamlessly contact each other in the second mode.

Meanwhile, an angle between the first link member and the second link member in the second mode may be greater than an angle between the first link member and the second link member in the first mode. Accordingly, the first structure and the second structure may be spaced apart from each other in the first mode, and the first structure and the second structure may seamlessly contact each other in the second mode.

Meanwhile, only the second link member may project out of the first structure in the second mode, and both the first link member and the second link member may project out of the first structure in the first mode. Accordingly, the first structure and the second structure may be spaced apart from each other in the first mode, and the first structure and the second structure may seamlessly contact each other in the second mode.

Meanwhile, the first link member in the first mode may project out of the first structure. Accordingly, the first structure and the second structure may be spaced apart from each other in the first mode, and the first structure and the second structure may seamlessly contact each other in the second mode.

Meanwhile, the first diagonal direction may correspond to an opening direction of the first guide groove in the second shaft, and the second diagonal direction may correspond to an opening direction of the second guide groove in the fourth shaft. Accordingly, the first structure and the second structure may be spaced apart from each other in the first mode, and the first structure and the second structure may seamlessly contact each other in the second mode.

Meanwhile, the first surface of the first structure and the first surface of the second structure may be spaced apart from each other and located on a same line in the first mode. Accordingly, the first structure and the second structure may be spaced apart from each other in the first mode, and the first structure and the second structure may seamlessly contact each other in the second mode.

Meanwhile, a distance between the first shaft and the second shaft in the second mode may be equal to a distance between the first shaft and the second shaft in the first mode, and a distance between the first shaft and the third shaft in the second mode may be equal to a distance between the first shaft and the third shaft in the first mode. Accordingly, the first structure and the second structure may be spaced apart from each other in the first mode, and the first structure and the second structure may seamlessly contact each other in the second mode.

Meanwhile, the distance between the first shaft and the third shaft may be greater than the distance between the first shaft and the second shaft in the second mode, and the distance between the first shaft and the third shaft may be greater than the distance between the first shaft and the second shaft in the first mode. Accordingly, the first structure and the second structure may be spaced apart from each other in the first mode, and the first structure and the second structure may seamlessly contact each other in the second mode.

Meanwhile, a distance between the second shaft and the third shaft in the first mode may be less than a distance between the second shaft and the third shaft in the second mode. Accordingly, the first structure and the second structure may be spaced apart from each other in the first mode, and the first structure and the second structure may seamlessly contact each other in the second mode.

Meanwhile, the hinge device according to an embodiment of the present disclosure may further include: a fifth link member contacted between a first display element and a second surface intersecting the first surface of the first structure; and a sixth link member contacted between a second display element and a second surface intersecting the first surface of the second structure. Accordingly, the first display element and the second display element may seamlessly contact each other.

Meanwhile, a side surface of the first display element may be contacted with a side surface of the second display element in the second mode, and the first display element and the second display element may be spaced apart from each other in the first mode. Accordingly, the first display element and the second display element may be spaced apart from each other in the first mode, and the first display element and the second display element may seamlessly contact each other in the second mode.

Meanwhile, the first display element and the second display element may include right-angled triangular display elements. Accordingly, the first display element and the second display element may seamlessly contact each other.

Meanwhile, a hinge device according to another embodiment of the present disclosure comprises: a first structure having a first guide groove formed in a first diagonal direction; a second structure having a second guide groove formed in a second diagonal direction; a first shaft disposed between the first structure and the second structure and spaced apart from the first structure and the second structure; a first link member connecting the first shaft to a second shaft formed in the first structure; a second link member connecting the first shaft to a third shaft moved in the first guide groove of the first structure; a third link member connecting the first shaft to a fourth shaft formed in the second structure; and a fourth link member connecting the first shaft to a fifth shaft moved in the second guide groove of the second structure, wherein, in a second mode, a first surface of the first structure is contacted with a first surface of the second structure, and, in a first mode, the first t structure is spaced apart from the second structure. Accordingly, the first structure and the second structure may seamlessly contact each other. Particularly, the first structure and the second structure may seamlessly contact each other while avoiding interference in a moving path during movement of the first structure and the second structure.

Meanwhile, an image display apparatus according to an embodiment of the present disclosure comprises a hinge device. Accordingly, the first display element and the second display element may be spaced apart from each other in the first mode, and the first display element and the second display element may seamlessly contact each other in the second mode.

Meanwhile, the image display apparatus according to an embodiment of the present disclosure may further include a plurality of display elements, wherein the plurality of display elements may be folded in a direction of the first shaft in the first mode, and at least a portion of the plurality of display elements may be unfolded to form a polyhedral display. Accordingly, it is possible to implement a display apparatus capable of being folded or unfolded by using the hinge device and the plurality of display elements. Particularly, a cuboid-shaped display apparatus may be implemented.

Meanwhile, the plurality of display elements may include right-angled triangular origami display elements. Accordingly, it is possible to implement a display apparatus capable of being folded or unfolded by using the hinge device and the plurality of display elements.

### BRIEF DESCRIPTION OF THE DRAWINGS

FIG. 1A is a diagram illustrating an example of a display apparatus associated with the present disclosure.

FIG. 1B is a diagram illustrating a hinge device associated with the present disclosure.

FIG. 2A is a diagram illustrating another example of a display apparatus associated with the present disclosure.

FIGS. 2B to 2F are diagrams referred to in the description of FIG. 2A.

FIG. 3A is a diagram illustrating an outer appearance of a display apparatus according to an embodiment of the present disclosure.

FIGS. 3B to 3D are diagrams referred to in the description of FIG. 3A.

FIG. 4A is a diagram illustrating a hinge device according to an embodiment of the present disclosure.

FIGS. 4B to 9B are diagrams referred to in the description of FIG. 4A.

### DETAILED DESCRIPTION

Hereinafter, the present disclosure will be described in detail with reference to the accompanying drawings. In order to clearly and briefly describe the present disclosure, components that are irrelevant to the description will be omitted in the drawings. The same reference numerals are used throughout the drawings to designate the same or similar components.

It will be understood that, although the terms first, second, etc., may be used herein to describe various elements, these elements should not be limited by these terms. These terms are only used to distinguish one element from another.

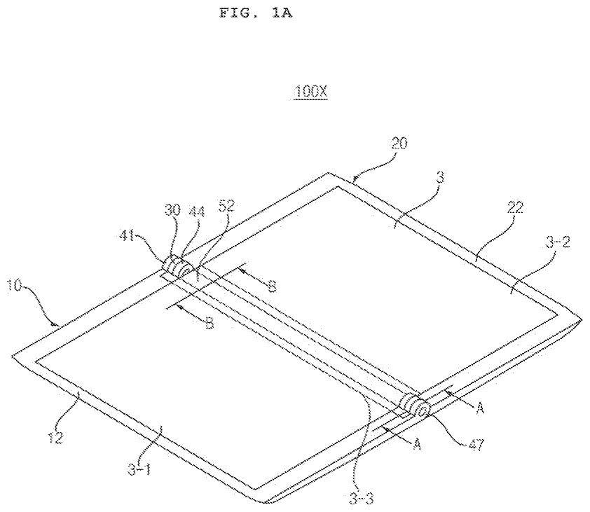

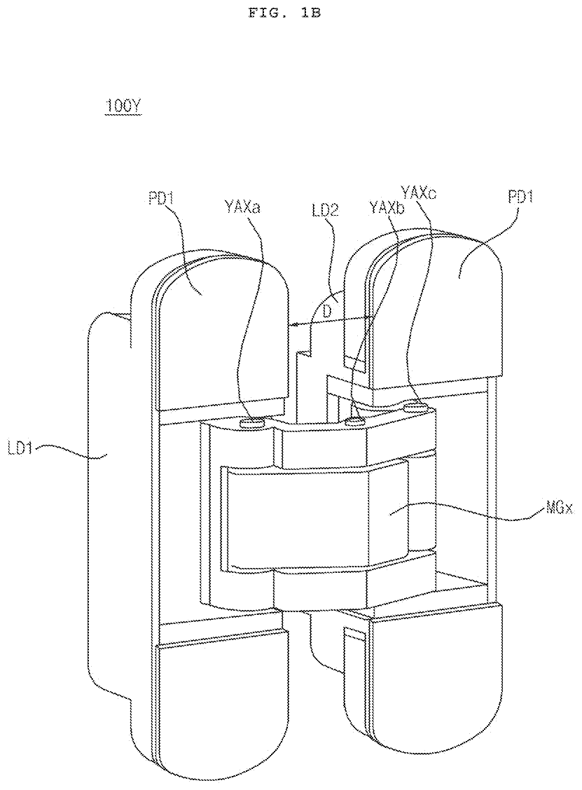

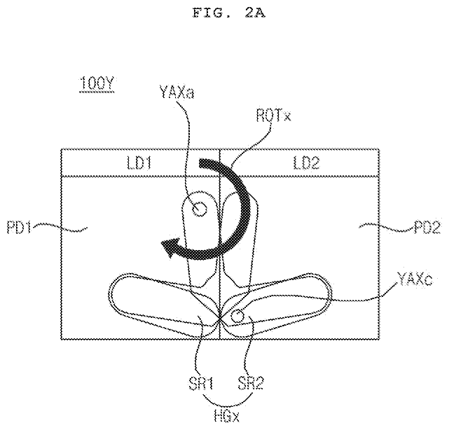

FIG. 1A is a diagram illustrating an example of a display apparatus associated with the present disclosure.

Referring to the drawing, in a display apparatus 100x associated with the present disclosure, a hinge device 52 is used to fold or unfold a first display 3 disposed in a first case 20 and a second display 3-1 disposed in a second case 10.

The hinge device 52 includes a shaft 47, and a plurality of coupling members 30, 41, and 44 to which the shaft 47 is coupled.

However, the hinge device 52 of FIG. 1A projects above the first display 3 and the second display 3-1, such that it is difficult to form a seamless gap between the first display 3 and the second display 3-1.

FIG. 1B is a diagram illustrating a hinge device associated with the present disclosure.

Referring to the drawing, in a hinge device HGx of FIG. 1B, a groove is formed between each of a first frame PD1 and a second frame PD2, and a linkage MGX is disposed in each groove.

The linkage MGX is connected to the first frame PD1 by a first shaft YAXa and connected to the second frame PD2 by a second shaft YAXc, and is rotated by a third shaft YAXb to be folded or unfolded.

Meanwhile, a hinge device 100y of FIG. 1B has a drawback in that one surface LD1 of the first frame PD1 and one surface LD2 of the second frame PD2 are spaced apart by a gap D, with no interference between the first frame PD1 and the second frame PD2, but may not be seamlessly connected.

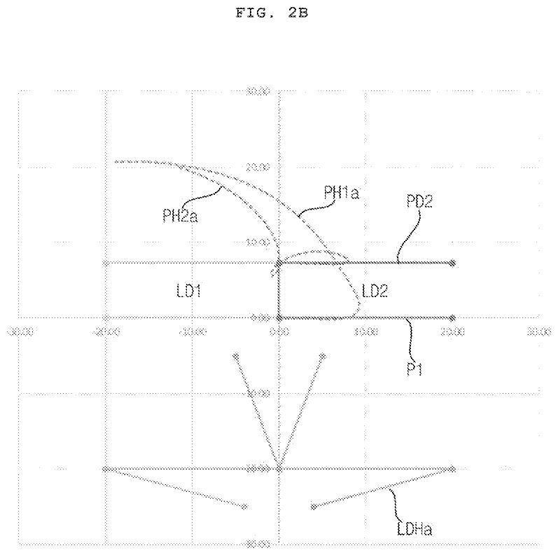

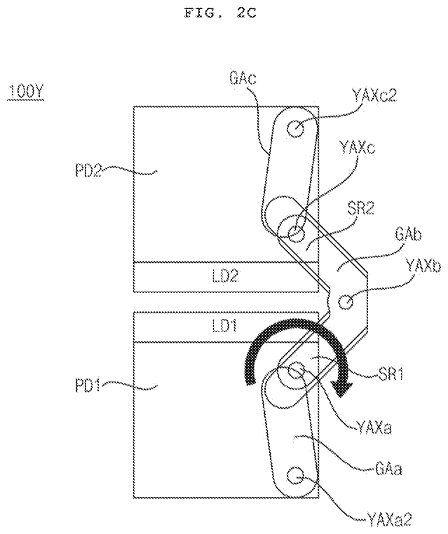

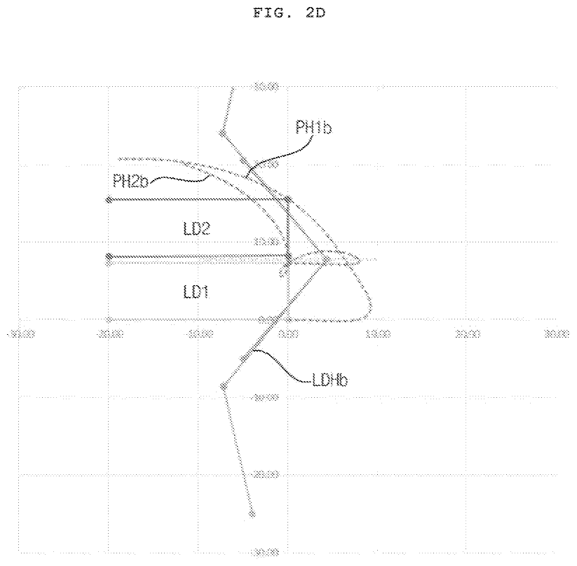

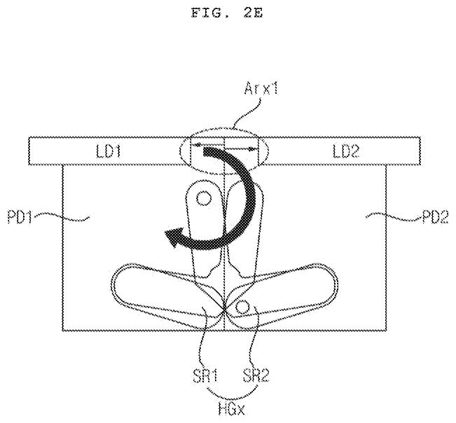

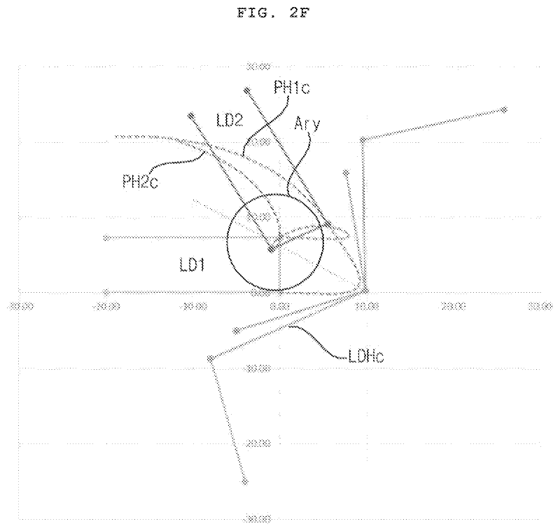

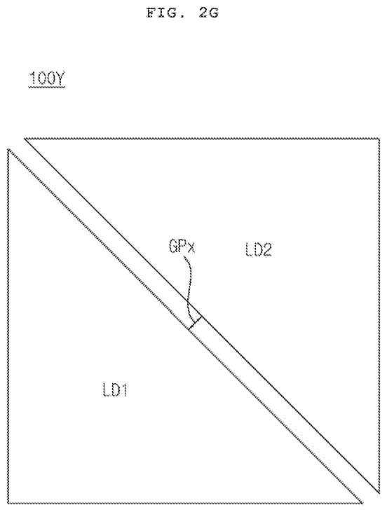

FIG. 2A is a diagram illustrating another example of a display apparatus associated with the present disclosure, and FIGS. 2B to 2F are diagrams referred to in the description of FIG. 2A.

Referring to the drawings, the display apparatus 100y associated with the present disclosure comprises a first frame PD1, a second frame PD2, and a hinge device HGx between the first frame PD1 and the second frame PD2.

By driving the hinge device HGx, the first frame PD1 or the second frame PD2 may rotate along a moving path ROTx.

The first display LD1 is disposed at the top of the first frame PD1, and the second display LD2 is disposed at the top of the second frame PD2.

FIG. 2A illustrates an example in which the hinge device 100y is opened, such that a side surface of the second frame PD2 is disposed on a side surface of the first frame PD1.

FIG. 2B is a diagram illustrating a moving path of each of the first frame PD1, the second frame PD2, and the hinge device HGx of FIG. 2A.

Referring to the drawing, Pb denotes an upper surface of the second display LD2, Pa denotes a lower surface of the second display LD2, PH2a denotes a moving path of the upper surface of the second display LD2, and PH1a denotes a moving path of the lower surface of the second display LD2.

FIG. 2B illustrates an example in which the first frame PD1 and the first display LDI are fixed, and the second frame PD2 and the second display LD2 move.

Meanwhile, LDHa denotes a link path of the hinge device HGx.

FIG. 2C illustrates an example in which the hinge device 100y is closed, such that the first frame PD1 and the second frame PD2 face each other.

Referring to the drawing, a distance between a first portion GAa and a second portion GAb in the hinge device HGx increases during rotation of the shaft YAXa, and a distance between the second portion GAb and a third portion GAc increases during rotatithe shaft YAXc.

By driving the hinge device HGx, the first frame PD1 or the second frame PD2 may rotate along a moving path ROTy.

FIG. 2D is a diagram illustrating a moving path of each of the first frame PD1, the second frame PD2, and the hinge device HGx.

Referring to the drawing, PH2b denotes a moving path of an upper surface of the second display LD2, PH1b denotes a moving path of a lower surface of the second display LD2, and LDHb denotes a link path of the hinge device HGx.

FIG. 2E illustrates an example in which the hinge device 100y is opened such that a side surface of the second frame PD2 is disposed on a side surface of the first frame PD1, but the first frame PD1 and the second frame PD2 are spaced apart by a gap Arx1 due to interference of the hinge device HGx.

Meanwhile, by driving the hinge device HGx, the first frame PD1 or the second frame PD2 may rotate along a moving path ROTx.

FIG. 2F is a diagram illustrating a moving path of each of the first frame PD1, the second frame PD2, and the hinge device HGx.

Referring to the drawing, PH2c denotes a moving path of an upper surface of the second display LD2, PH1c denotes a moving path of a lower surface of the second display LD2, and LDHc denotes a link path of the hinge device HGx.

As illustrated herein, during operation of the hinge device HGx, interference may occur in a moving path PH2c of the upper surface of the second display LD2, such that a gap is formed between the side surface of the first frame PD1 and the side surface of the second frame PD2 as illustrated in FIG. 2F. Accordingly, there is a drawback in that it is difficult to form a seamless connection.

FIG. 2G illustrates an example in which the hinge device 100y is opened such that a side surface of the second frame PD2 is disposed on a side surface of the first frame PD1, but a gap GPx is formed between the first display LD1 and the second display LD2 due to interference and the like during operation of the hinge device HGx. Accordingly, there is a drawback in that it is difficult to form a seamless connection.

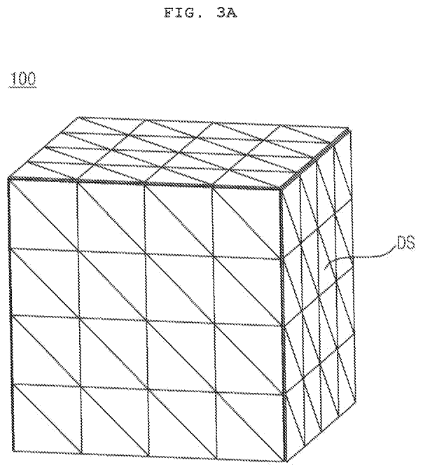

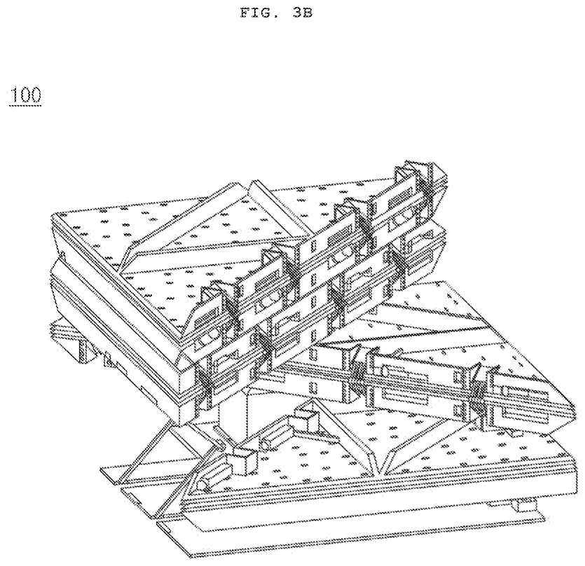

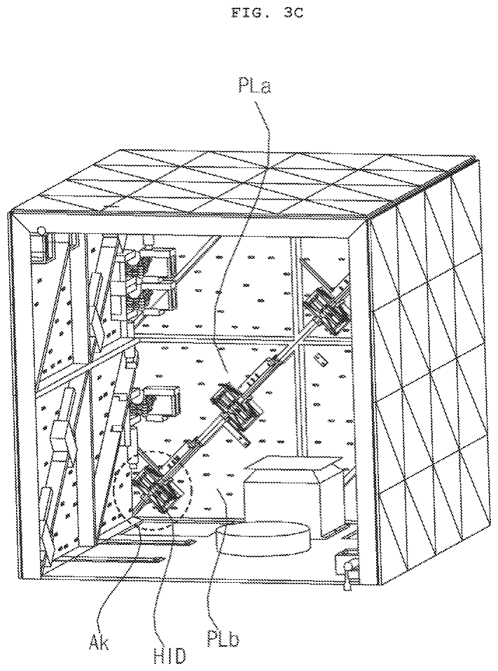

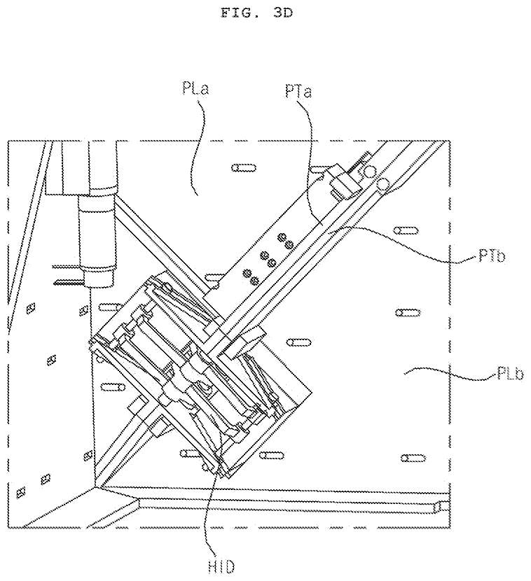

Accordingly, the present disclosure proposes a hinge device capable of seamlessly contacting a first structure and a second structure. Particularly, the present disclosure proposes a hinge device capable of seamlessly contacting a first structure and a second structure while avoiding interference in a moving path during movement of the first structure and the second structure, which will be described below with reference to FIG. 3A and subsequent figures.

FIG. 3A is a diagram illustrating an outer appearance of a display apparatus according to an embodiment of the present disclosure, and FIGS. 3B to 3D are diagrams referred to in the description of FIG. 3A.

Referring to FIG. 3A, a display apparatus 100 according to an embodiment of the present disclosure comprises triangular origami display elements DS.

Meanwhile, although not illustrated herein, a housing (not shown) may be disposed at a lower portion of the display apparatus 100, and a plurality of display elements DS may be disposed in the housing (not shown) in a first mode, and then may project out of the housing (not shown) to be unfolded in a second mode.

Meanwhile, the display apparatus 100 according to an embodiment of the present disclosure may be folded or unfolded by using the plurality of display elements DS via an internal hinge device HID and the like.

FIG. 3B illustrates the display apparatus 100 with the plurality of display elements DS that are folded.

FIG. 3C is a diagram illustrating a rear surface of the display apparatus 100 of FIG. 3A according to an embodiment of the present disclosure.

Referring to the drawings, the display apparatus 100 includes a first display element PLa, a second display element PLb, and a hinge device HID disposed between the first display element PLa and the second display element PLb. In the drawings, the hinge device HID is provided in an area Ak.

Meanwhile, the first display element PLa and the second display element PLb may include origami display elements.

Particularly, the first display element PLa and the second display element PLb may include right-angled triangular display elements, as illustrated herein.

FIG. 3D is an enlarged view of the hinge device HID of FIG. 3A.

Referring to the drawing, the hinge device HID is disposed between the first display element PLa and the second display element PLb.

Particularly, the hinge device HID is disposed between a rear frame PTa of the first display element PLa and a rear frame PTb of the second display element PLb.

Meanwhile, according to an embodiment of the present disclosure, the first display element PLa and the second display element PLb are spaced apart from each other, and a first surface of the first display element PLa and a first surface of the second display element PLb may make contact with each other in a second mode. Accordingly, the first display element PLa and the second display element PLb may be spaced apart from each other in the first mode, and the first display element PLa and the second display element PLb may seamlessly contact each other in the second mode.

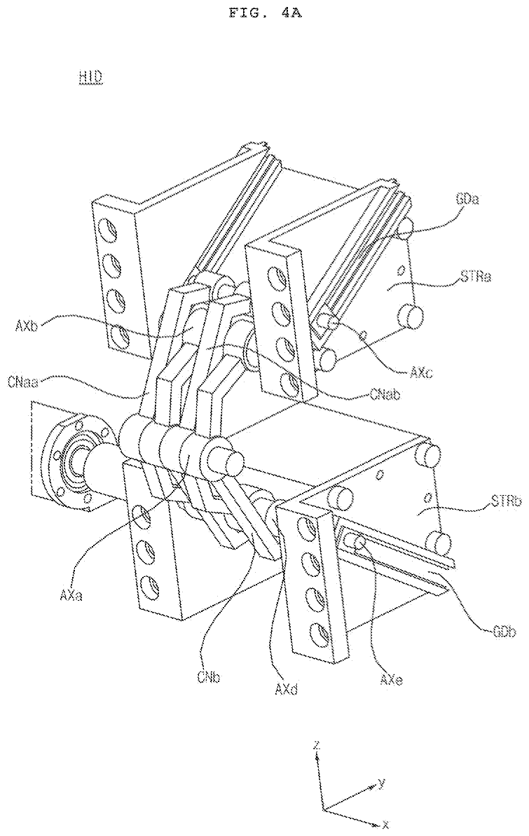

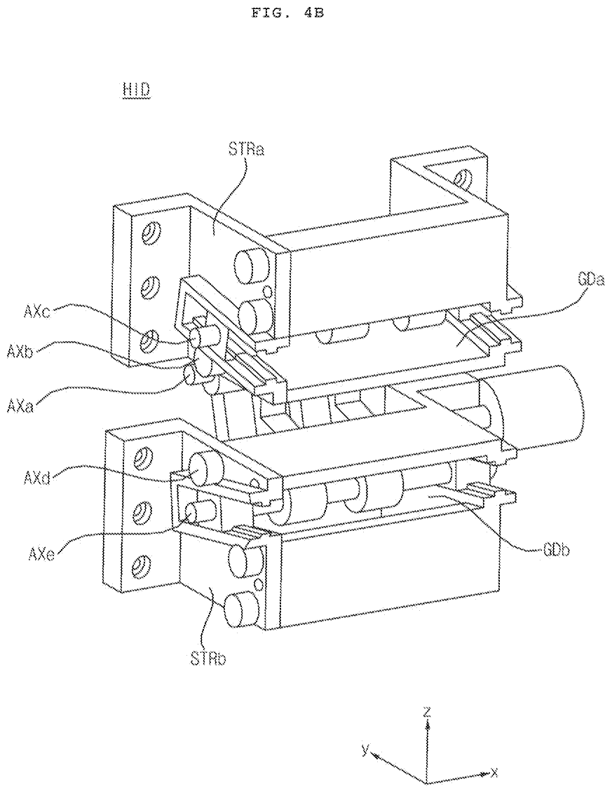

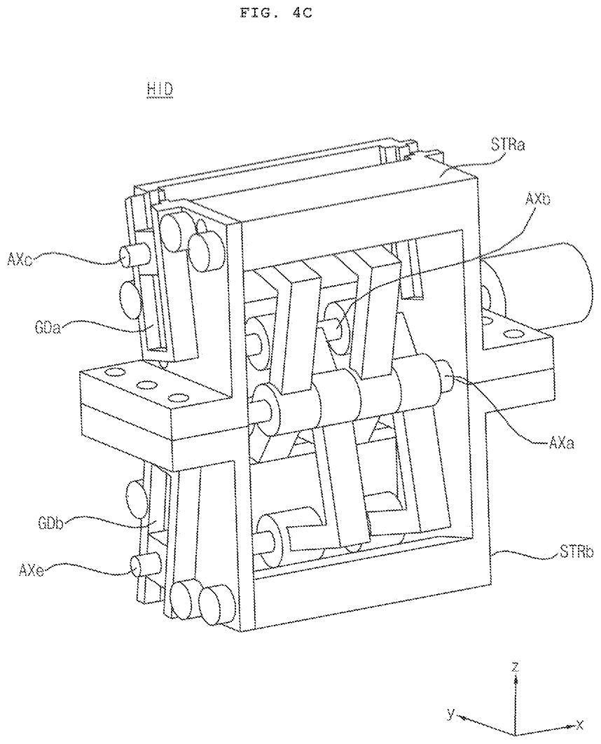

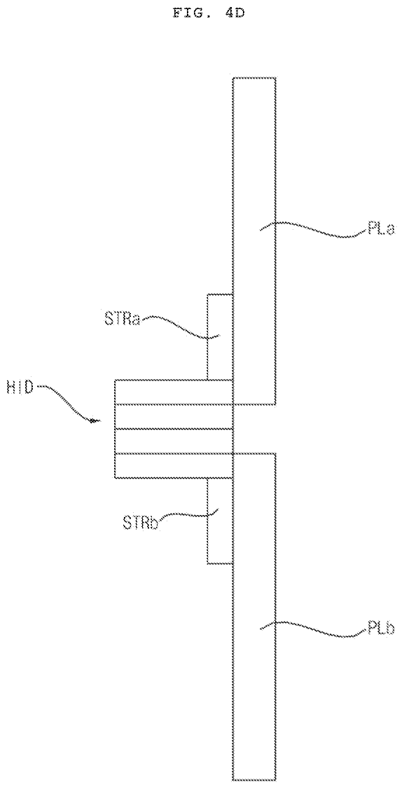

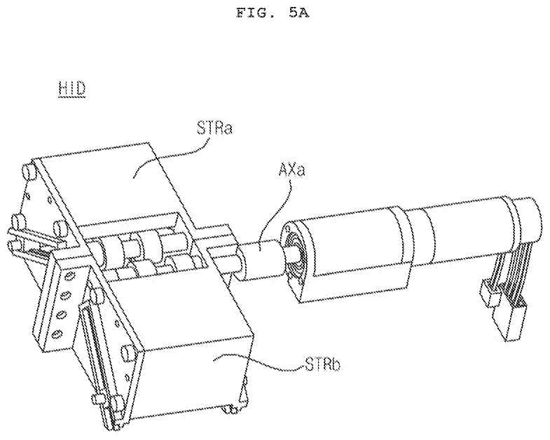

Meanwhile, the hinge device HID according to an embodiment of the present disclosure will be described below with reference to FIG. 4A and subsequent figures.

FIG. 4A is a diagram illustrating a hinge device according to an embodiment of the present disclosure, and FIGS. 4B to 9B are diagrams referred to in the description of FIG. 4A.

First, referring to FIG. 4A, the hinge device HID according to an embodiment of the present disclosure comprises a first structure STRa having a first guide groove GDa formed in a first diagonal direction, a second structure STRb having a second guide groove GDb formed in a second diagonal direction, a first shaft Axa disposed between the first structure STRa and the second structure STRb and spaced apart from the first structure and the second structure, a first link member CNaa connecting the first shaft Axa to a second shaft Axb formed in the first structure STRa, a second link member CNab connecting the first shaft Axa to a third shaft Axc moving in the first guide groove GDa of the first structure STRa, a third link member CNba connecting the first shaft Axa to a fourth shaft Axd formed in the second structure STRb, and a fourth link member CNbb connecting the first shaft Axa to a fifth shaft Axe moving in the second guide groove GDb of the second structure STRb.

Meanwhile, it is preferable that the second link member CNab has a greater length than the first link member CNaa, and the fourth link member CNbb has a greater length than the third link member CNba.

Accordingly, movement of the second link member CNab is greater than movement of the first link member CNaa, and movement of the fourth member CNbb is greater than movement of the third link member CNba.

Accordingly, the first structure STRa and the second structure STRb may seamlessly contact each other. Particularly, the first structure STRa and the second structure STRb may seamlessly contact each other while avoiding interference in the moving path during movement of the first structure STRa and the second structure STRb.

Meanwhile, the first diagonal direction corresponds to an opening direction of the first guide groove GDa in the second shaft Axb, and the second diagonal direction corresponds to an opening direction of the second guide groove GDb in the fourth shaft Axd. Accordingly, the first structure STRa and the second structure STRb may be spaced apart from each other in the first mode, and the first structure STRa and the second structure STRb may seamlessly contact each other in the second mode.

Meanwhile, FIG. 4A illustrates an example in which the hinge device HID operates in the first mode. That is, the first structure STRa and the second structure STRb are spaced apart from each other in the z-axis direction.

Particularly, the second structure STRb is spaced below the first structure STRa in the z-axis direction. Accordingly, the display elements may be folded as illustrated in FIG. 3B.

FIG. 4B is a diagram illustrating a rear surface of the hinge device HID of FIG. 4A.

As described above, as the hinge device HID operates in the first mode, the second structure STRb is spaced below the first structure STRa in the z-axis direction.

FIG. 4C is a diagram illustrating an example in which the hinge device HID of FIG. 4A operates in the second mode.

Meanwhile, referring to the drawing, a first surface of the first structure STRa and a first surface of the second structure STRb make contact with each other in the second mode.

Accordingly, the first structure STRa and the second structure STRb may seamlessly contact each other while avoiding interference in the moving path during movement of the first structure STRa and the second structure STRb.

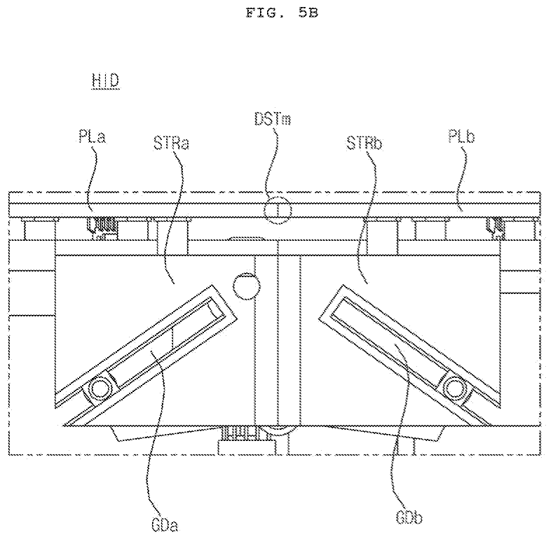

FIGS. 5A and 5B are diagrams referred to in the description of operation of the hinge device HID in the second mode.

FIG. 5A illustrates an example in which a motor is coupled to a first shaft Axa. For example, the first shaft Axa may be rotated by a first operation of the motor.

Accordingly, as illustrated herein, a first surface of the first structure STRa and a first surface of the second structure STRb may make contact with each other. Particularly, the first structure STRa and the second structure STRb may seamlessly contact each other in the second mode.

FIG. 5B is a side view of the hinge device HID of FIG. 5A.

Referring to the drawing, the third shaft Axc is disposed in the first guide groove GDa formed in the first diagonal direction, and the fifth shaft Axe is disposed and moves in the second guide groove GDb formed in the second diagonal direction.

Meanwhile, the hinge device HID according to an embodiment of the present disclosure may further include a fifth link member CNe contacted between the first display element PLa and a second surface intersecting the first surface of the first structure STRa, and a sixth link member CNf contacted between the second display element PLb and a second surface intersecting the first surface of the second structure STRb. Accordingly, the first display element PLa and the second display element PLb may seamlessly contact each other.

Meanwhile, a side surface of the first display element PLa may be contacted with a side surface of the second display element PLb in the second mode.

In the drawing, an area DSTm is illustrated in which the side surface of the first display element PLa and the side surface of the second display element PLb make contact with each other, and the area DSTm may be a seamless area in which no gap is formed, and no interference occurs. Accordingly, the first display element PLa and the second display element PLb may seamlessly contact each other in the second mode.

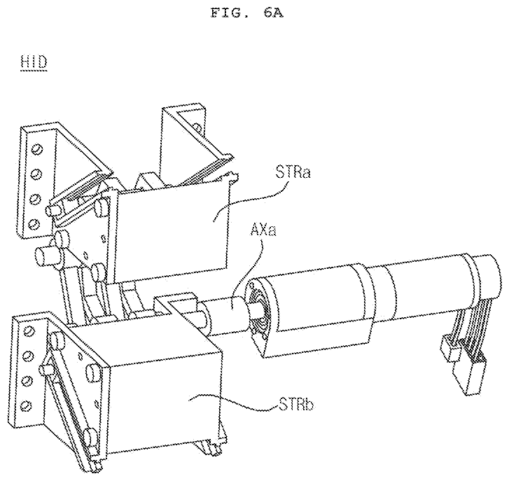

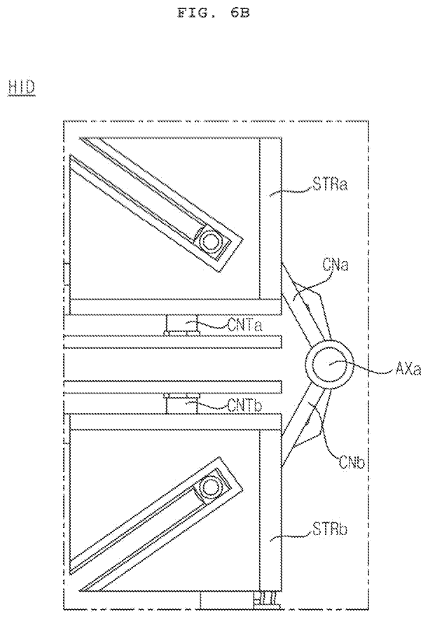

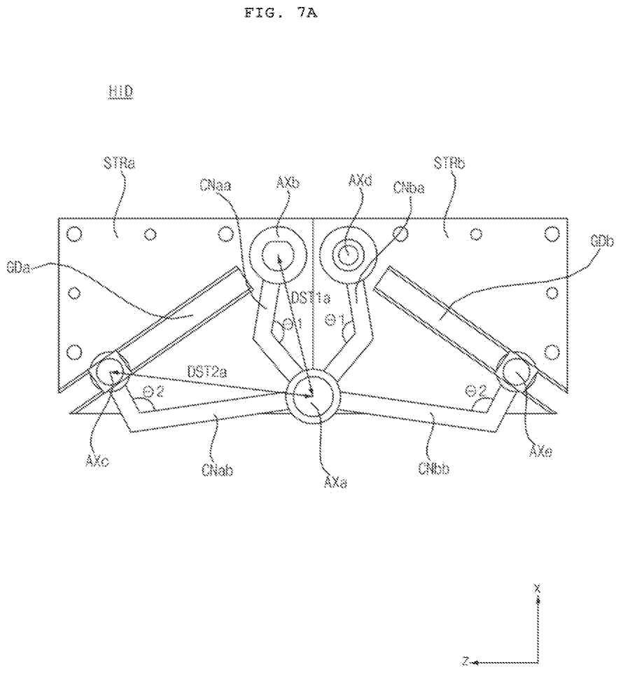

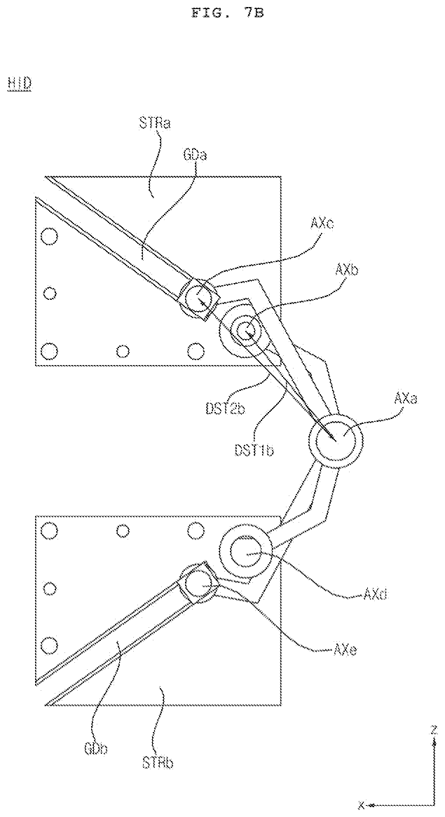

FIGS. 6A and 6B are diagrams referred to in the description of operation of the hinge device HID in the first mode.

FIG. 6A illustrates an example in which a motor is coupled to a first shaft Axa. For example, the first shaft Axa may be rotated by a second operation of the motor.

Accordingly, as illustrated herein, the first structure STRa and the second structure STRb may be spaced apart from each other.

FIG. 6B is a side view of the hinge device HID of FIG. 6A.

Referring to the drawing, the third shaft Axc is disposed in the first guide groove GDa formed in the first diagonal direction, and the fifth shaft Axe is disposed and moves in the second guide groove GDb formed in the second diagonal direction.

Meanwhile, the hinge device HID according to an embodiment of the present disclosure may further include the fifth link member CNe contacted with the first structure STRa, and the sixth link member CNf contacted with the second structure STRb.

Meanwhile, as the second structure STRb is spaced below the first structure STRa, the second display element PLb is spaced below the first display element PLa. As a result, the display elements PLa and PLb may be folded as illustrated in FIG. 3B.

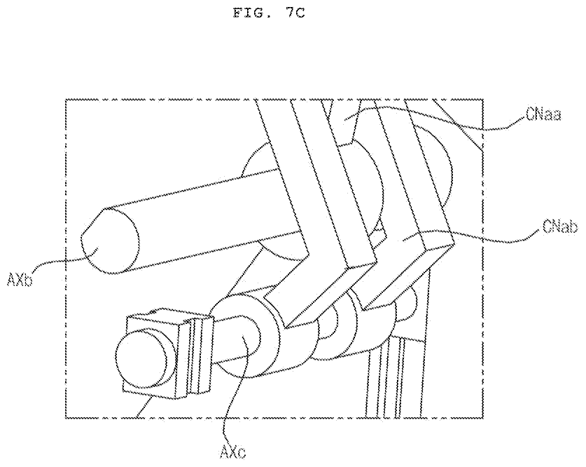

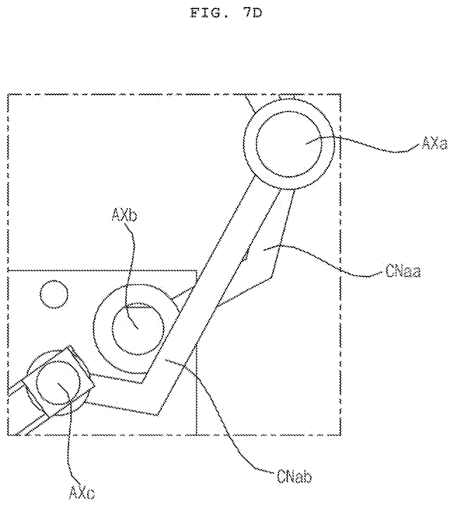

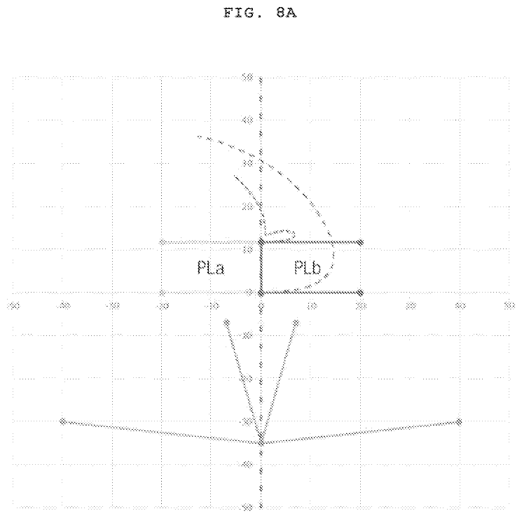

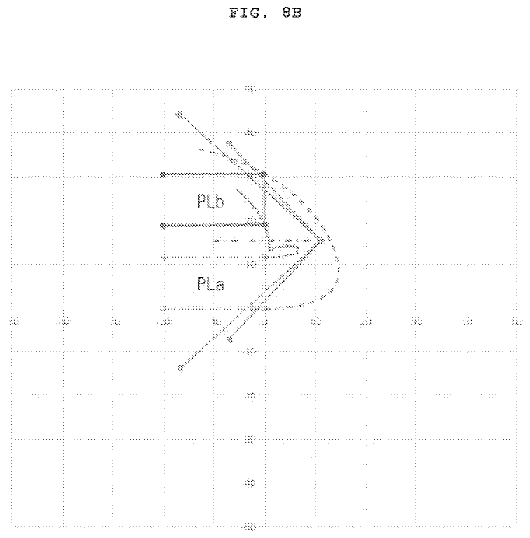

FIG. 7A is a side view of the hinge device HID operating in the second mode.

Referring to the drawing, the third shaft Axc is disposed at a first position P1 in the first guide groove GDa in the second mode, and the first position P1 may correspond to a furthest position from the third shaft Axc.

Meanwhile, the fifth shaft Axe is disposed at a third position P3 in the second guide groove GDb in the second mode, and the third position P3 may correspond to a furthest position from the fifth shaft Axe. Accordingly, the first structure STRa and the second structure STRb may seamlessly contact each other in the second mode.

Meanwhile, the second link member CNab may preferably have a greater length than the first link member CNaa. Accordingly, the third shaft Axc, which moves in the first guide groove GDa, may move smoothly.

Meanwhile, the fourth link member CNbb may preferably have a greater length than the third link member CNba. Accordingly, the fifth shaft Axe, which moves in the second guide groove GDb, may move smoothly.

Meanwhile, the first link member CNaa to the fourth link member CNbb preferably have a bent structure, particularly, an “inverted L-shape,” in order to avoid interference with the shaft and to serve as a stopper after stroke is completed.

Meanwhile, an angle θ1 between the first link member CNaa and the second link member CNbb in the second mode is preferably greater than an angle θ2 between the first link member CNaa and the second link member CNbb in the first mode. Accordingly, the third shaft Axc, which moves in the first guide groove GDa, may move smoothly.

Meanwhile, a distance between the first shaft Axa and the third shaft Axc is preferably greater than a distance DST1a between the first shaft Axa and the second shaft Axb in the second mode. Accordingly, the third shaft Axc, which moves in the first guide groove GDa, may move smoothly.

Meanwhile, a distance between the first shaft Axa and the fifth shaft Axe is preferably greater than a distance between the first shaft Axa and the fourth shaft Axd in the second mode. Accordingly, the fifth shaft Axe, which moves in the second guide groove GDb, may move smoothly.

FIG. 7B is a side view of the hinge device HID operating in the first mode.

Referring to the drawing, the third shaft Axc is disposed at the second position P2 in the first guide groove GDa in the first mode, and the second position P2 may correspond to a closest position to the third shaft Axc.

Meanwhile, the fifth shaft Axe is disposed at a fourth position P4 in the second guide groove GDb in the first mode, and the fourth position P4 may correspond to a closest position to the fifth shaft Axe. Accordingly, the first structure STRa and the second structure STRb may be spaced apart from each other in the first mode.

Meanwhile, in response to switching from the second mode to the first mode, i.e., switching from FIG. 7A to FIG. 7B, the third shaft Axc moves from the first position to the second position.

Meanwhile, in response to switching from the first mode to the second mode, i.e. switching from FIG. 7B to FIG. 7A, the third shaft Axc moves from the second position to the first position.

Accordingly, the first structure STRa and the second structure STRb may be spaced apart from each other in the first mode, and the first structure STRa and the second structure STRb may seamlessly contact each other in the second mode.

Meanwhile, only the second link member CNab may project out of the first structure STRa in the second mode as illustrated in FIG. 7A, and both the first link member CNaa and the second link member CNab may project out of the first structure STRa in the first mode as illustrated in FIG. 7B.

Particularly, in the first mode as illustrated in FIG. 7B, the first link member CNaa may project out of the first structure STRa.

Meanwhile, in the first mode as illustrated in FIG. 7B, the first surface of the first structure STRa and the first surface of the second structure STRb are spaced apart from each other and may be located on the same line. Accordingly, the first structure STRa and the second structure STRb may be spaced apart from each other in the first mode.

Meanwhile, a distance between the first shaft Axa and the second shaft Axb in the second mode s illustrated in FIG. 7A may be equal to a distance between the first shaft Axa and the second shaft Axb in the first mode as illustrated in FIG. 7B, and a distance between the first shaft Axa and the third shaft Axc in the second mode as illustrated in FIG. 7A may be equal to a distance between the first shaft Axa and the third shaft Axc in the first mode as illustrated in FIG. 7B.

That is, the distance between the first shaft Axa and the second shaft Axb is preferably the same regardless of the first mode or the second mode.

Similarly, the distance between the first shaft Axa and the third shaft Axc is preferably the same regardless of the first mode or the second mode.

Meanwhile, in comparison of FIGS. 7A and 7B, the distance between the second shaft Axb and the third shaft Axc in the first mode of FIG. 7B is preferably less than the distance between the second shaft Axb and the third shaft Axc in the second mode of FIG. 7A.

In the first mode, the third shaft Axc is disposed at the second position in the first guide groove GDa, and the second position corresponds to a closest position to the third shaft Axc, such that the distance between the second shaft Axb and the third shaft Axc in the first mode of FIG. 7B is smaller.

Accordingly, the first structure STRa and the second structure STRb may be spaced apart from each other in the first mode, and the first structure STRa and the second structure STRb may seamlessly contact each other in the second mode.

FIG. 7C is an enlarged view of the second shaft Axb, the third shaft Axc, the first link member CNaa, and the second link member CNab of FIG. 4A, and FIG. 7D is a side view of FIG. 7C.

Referring to the drawing, the first link member CNaa and the second link member CNab are preferably provided in plurality. Accordingly, stable rotation may be obtained without damage.

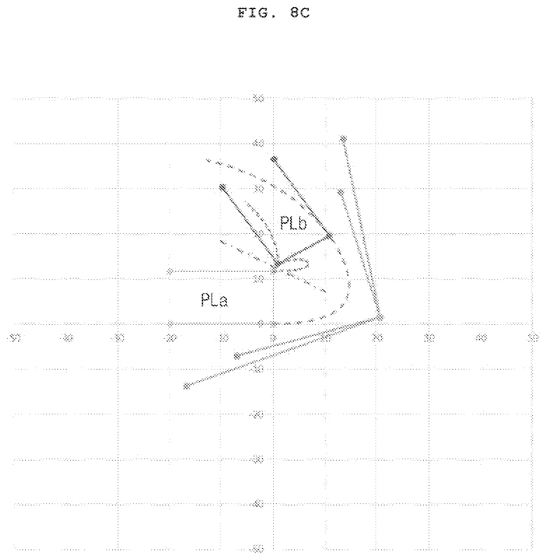

FIG. 8A is a diagram illustrating movement of the fist structure STRa and the second structure STRb in the hinge device HID in the second mode.

Particularly, FIG. 8A illustrates an example in which the first structure STRa of the hinge device HID and the first display element PLa are fixed, and the second structure STRb and the second display element PLb move.

Particularly, of a path of the upper surface and a path of the lower surface of the second structure STRb or the second display element PLb, the path of the upper surface is shorter than the path of the lower surface and is simplified.

Accordingly, the possibility of interference between the first structure STRa and the second structure STRb is reduced.

Meanwhile, a link path of at least one of the first link member CNaa to the fourth link member CNbb in the hinge device HID is symmetrical about a vertical axis which is a boundary between the first display element PLa and the second display element PLb, as illustrated herein. Accordingly, the possibility of interference between the first structure STRa and the second structure STRb reduced, and the display apparatus 100 may be implemented seamlessly.

FIG. 8B is a diagram illustrating movement of the first structure STRa and the second structure STRb in the hinge device HID in the first mode.

Particularly, FIG. 8B illustrates an example in which the first structure STRa of the hinge device HID and the first display element PLa are fixed, and the second structure STRb and the second display element PLb move.

Referring to the drawing, the second structure STRb and the second display element PLb are disposed above the first structure STRa and the first display element PLa.

To this end, the second structure STRb and the second display element PLb move, and particularly, of a path of the upper surface and a path of the lower surface of the second structure STRb or the second display element PLb, the path of the upper surface is shorter than the path of the lower surface and is simplified.

Accordingly, the possibility of interference between the first structure STRa and the second structure STRb is reduced.

Meanwhile, a link path of at least one of the first link member CNaa to the fourth link member CNbb in the hinge device HID is symmetrical about a horizontal axis which is a boundary between the first display element PLa and the second display element PLb, as illustrated herein. Accordingly, the possibility of interference between the first structure STRa and the second structure STRb is reduced, and the display apparatus 100 may be implemented seamlessly.

FIG. 8C is a diagram illustrating movement of the first structure STRa and the second structure STRb in the hinge device HID in a third mode between the second mode and the first mode.

Particularly, FIG. 8C illustrates an example in which the first structure STRa and the first display element PLa are fixed, and the second structure STRb and the second display element PLb move.

Referring to the drawing, the second structure STRb and the second display element PLb are disposed in a rightward diagonal direction of the first structure STRa and the first display element PLa.

To this end, the second structure STRb and the second display element PLb move, and particularly, of a path of the upper surface and a path of the lower surface of the second structure STRb or the second display element PLb, the path of the upper surface is shorter than the path of the lower surface and is simplified.

Accordingly, the possibility of interference between the first structure STRa and the second structure STRb is reduced.

Meanwhile, a link path of at least one of the first link member CNaa to the fourth link member CNbb in the hinge device HID is symmetrical in a diagonal direction which is a boundary between the first display element PLa and the second display element PLb, as illustrated herein. Accordingly, the possibility of interference between the first structure STRa and the second structure STRb is reduced, and the display apparatus 100 may be implemented seamlessly.

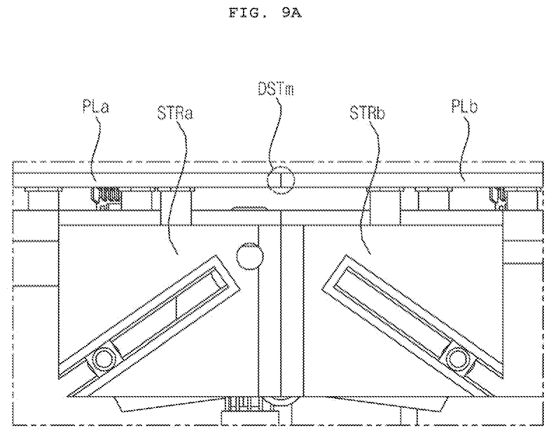

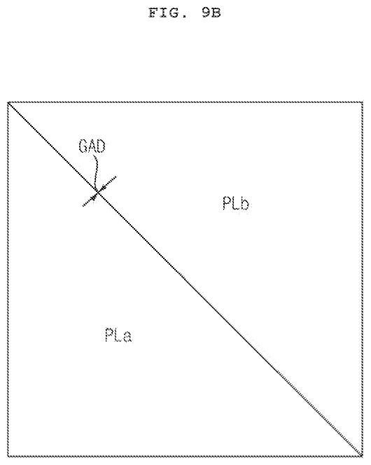

FIG. 9A is a side view of the hinge device HID of FIG. 5A that operates in the second mode.

Referring to the drawing, the third shaft Axc is disposed at the first position in the first guide groove GDa in the second mode, and the first position may correspond to a furthest position from the third shaft Axc.

Meanwhile, the fifth shaft Axe is disposed at the third position in the second guide groove GDb, and the third position may correspond to a furthest position from the fifth shaft Axe.

Accordingly, the first structure STRa and the second structure STRb may seamlessly contact each other in the second mode. Further, the side surface of the first display element PLa and the side surface of the second display element PLb may seamlessly contact each other.

In the drawing, an area DSTm is illustrated in which the side surface of the first display element PLa and the side surface of the second display element PLb make contact with each other, and the area DSTm may be a seamless area in which no gap is formed, and no interference occurs. Accordingly, the first display element PLa and the second display element PLb may seamlessly contact each other in the second mode.

FIG. 9B is a diagram illustrating an example in which the hinge device HID according to an embodiment of the present disclosure operates in the second mode, and the first display element PLa and the second display element PLb, which have a right-angled triangular shape, seamlessly contact each other.

As described above, a gap GAD is not formed between the first display element PLa and the second display element PLb, and may be implemented seamlessly without interference during operation of the hinge device HID.

Meanwhile, the hinge device HID according to another embodiment of the present disclosure comprises a first structure STRa having a first guide groove GDa formed in a first diagonal direction, a second structure STRb having a second guide groove GDb formed in a second diagonal direction, a first shaft Axa disposed between the first structure STRa and the second structure STRb and spaced apart from the first structure and the second structure, a first link member CNaa connecting the first shaft Axa to a second shaft Axb formed in the first structure STRa, a second link member CNab connecting the first shaft Axa to a third shaft Axc moving in the first guide groove GDa of the first structure STRa, a third link member CNba connecting the first shaft Axa to a fourth shaft Axd formed in the second structure STRb, and a fourth link member CNbb connecting the first shaft Axa to a fifth shaft Axe moving in the second guide groove GDb of the second structure STRb, in which a first surface of the first structure STRa and a first surface of the second structure STRb make contact with each other in the second mode, and the first structure STRa and the second structure STRb are spaced apart from each other in the first mode. Accordingly, the first structure STRa and the second structure STRb may seamlessly contact each other. Particularly, the first structure STRa and the second structure STRb may seamlessly contact each other while avoiding interference in the moving path during movement of the first structure STRa and the second structure STRb.

Meanwhile, the image display apparatus 100 according to an embodiment of the present disclosure comprises the aforementioned hinge device HID. Accordingly, the first display element PLa and the second display element PLb are spaced apart from each other in the first mode, and the first display element PLa and the second display element PLb may seamlessly contact each other in the second mode.

Meanwhile, the image display apparatus 100 according to an embodiment of the present disclosure may further include a plurality of display elements PLa and PLb, in which the plurality of display elements PLa and PLb are folded in a direction of the first shaft Axa in the first mode, and at least a portion of the plurality of display elements PLa and PLb are unfolded to form a polyhedral display.

Accordingly, it is possible to implement a display apparatus capable of being folded or unfolded by using the hinge device HID and the plurality of display elements PLa and PLb, as illustrated in FIG. 3B or FIG. 3A. Particularly, a cuboid-shaped display apparatus may be implemented.

Meanwhile, the plurality of display elements PLA and PLb may include right-angled triangular origami display elements. Accordingly, it is possible to implement a display apparatus capable of being folded or unfolded by using the hinge device HID and the plurality of display elements PLa and PLb.

Meanwhile, the aforementioned hinge device HID may be applied in various fields, such as photovoltaic panels, doors, vehicles, home appliances, medical devices, etc., as well as display apparatuses.

While the present disclosure has been particularly shown and described with reference to preferred embodiments thereof, it will be understood by those skilled in the art that the present disclosure is not limited to those exemplary embodiments and various changes in form and details may be made therein without departing from the scope and spirit of the disclosure as defined by claims, and such the appended modifications should not be individually understood from the technical spirit or prospect of the present disclosure.

What is claimed is:

1. A hinge device comprising:
a first structure having a first guide groove formed in a first diagonal direction;
a second structure having a second guide groove formed in a second diagonal direction;
a first shaft disposed between the first structure and the second structure and spaced apart from the first structure and the second structure;
a first link member connecting the first shaft to a second shaft formed in the first structure;
a second link member connecting the first shaft to a third shaft moved in the first guide groove of the first structure;
a third link member connecting the first shaft to a fourth shaft formed in the second structure; and
a fourth link member connecting the first shaft to a fifth shaft moved in the second guide groove of the second structure,
wherein a length of the second link member is greater than a length of the first link member, and a length of the fourth link member is greater than a length of the third link member.

2. The hinge device of claim 1, wherein, in a first mode, the first structure is spaced apart from and the second structure, and
wherein, in a second mode, a first surface of the first structure is contacted with a first surface of the second structure.

3. The hinge device of claim 2, wherein, in the second mode, the third shaft is disposed at a first position in the first guide groove, and
wherein, in the first mode, the third shaft is disposed at a second position in the first guide groove, and
wherein the first position corresponds to a furthest position from the third shaft, and the second position corresponds to a closest position to the third shaft.

4. The hinge device of claim 3, wherein, in response to switching from the second mode to the first mode, the third shaft moves from the first position to the second position, and
wherein, in response to switching from the first mode to the second mode, the third shaft moves from the second position to the first position.

5.The hinge device of claim 2, wherein an angle between the first link member and the second link member in the second mode is greater than an angle between the first link member and the second link member in the first mode.

6. The hinge device of claim 2, wherein, in the second mode, only the second link member projects out of the first structure, and
wherein, in the first mode, both the first link member and the second link member project out of the first structure.

7. The hinge device of claim 2, wherein, in the first mode, the first link member projects out of the first structure.

8. The hinge device of claim 2, wherein the first diagonal direction corresponds to an opening direction of the first guide groove in the second shaft, and
wherein the second diagonal direction corresponds to an opening direction of the second guide groove in the fourth shaft.

9. The hinge device of claim 2, wherein, in the first mode, the first surface of the first structure and the first surface of the second structure are spaced apart from each other and located on a same line.

10. The hinge device of claim 2, wherein a distance between the first shaft and the second shaft in the second mode is equal to a distance between the first shaft and the second shaft in the first mode, and
wherein a distance between the first shaft and the third shaft in the second mode is equal to a distance between the first shaft and the third shaft in the first mode.

11. The hinge device of claim 2, wherein the distance between the first shaft and the third shaft is greater than the distance between the first shaft and the second shaft in the second mode, and
wherein the distance between the first shaft and the third shaft is greater than the distance between the first shaft and the second shaft in the first mode.

12. The hinge device of claim 2, wherein a distance between the second shaft and the third shaft in the first mode is less than a distance between the second shaft and the third shaft in the second mode.

13. The hinge device of claim 2, further comprising:
a fifth link member contacted between a first display element and a second surface intersecting the first surface of the first structure; and
a sixth link member contacted between a second display element and a second surface intersecting the first surface of the second structure.

14. The hinge device of claim 13, wherein, in the second mode, a side surface of the first display element is contacted with a side surface of the second display element, and
wherein, in the first mode, the first display element is spaced apart from the second display element.

15. The hinge device of claim 13, wherein the first display element and the second display element comprise right-angled triangular display elements.

16. A hinge device comprising:
a first structure having a first guide groove formed in a first diagonal direction;
a second structure having a second guide groove formed in a second diagonal direction;
a first shaft disposed between the first structure and the second structure and spaced apart from the first structure and the second structure;
a first link member connecting the first shaft to a second shaft formed in the first structure;
a second link member connecting the first shaft to a third shaft moved in the first guide groove of the first structure;
a third link member connecting the first shaft to a fourth shaft formed in the second structure; and
a fourth link member connecting the first shaft to a fifth shaft moved in the second guide groove of the second structure,
wherein, in a second mode, a first surface of the first structure is contacted with a first surface of the second structure, and,
wherein, in a first mode, the first structure is spaced apart from the second structure.

17. A display apparatus comprising a hinge device of any one of claims 1 to 16.

18. The display apparatus of claim 17, further comprising a plurality of display elements,
wherein, in the first mode, the plurality of display elements are folded in a direction of the first shaft, and,
wherein, in the second mode, at least a portion of the plurality of display elements are unfolded to form a polyhedral display.

19. The display apparatus of claim 18,
wherein the plurality of display elements comprise right-angled triangular origami display elements.
